(19) United States
(12) Patent Application Publication
(10) Pub. No.: US 2026/0279413 A1
(43) Pub. Date: Sep. 17, 2026

(54) SEMICONDUCTOR STORAGE DEVICE AND MANUFACTURING METHOD THEREOF

(71) Applicant: Kioxia Corporation, Tokyo (JP)

(72) Inventors: Ryo KATO, Inabe Mie (JP); Kensei TAKAHASHI, Kuwana Mie (JP)

(21) Appl. No.: 19/327,468

(22) Filed: Sep. 12, 2025

(30) Foreign Application Priority Data
Mar. 12, 2025 (JP) 2025-039686

(51) Int. Cl. G11C 5/06; H10B 43/10; H10B 43/27; H10B 43/35; H10D 64/66; H10D 64/68

(52) U.S. Cl. CPC G11C 5/063; H10B 43/10; H10B 43/27; H10B 43/35; H10D 64/666; H10D 64/691

(57) ABSTRACT

A semiconductor storage device capable of securing higher reliability is provided. A semiconductor storage device includes a stacked body, a pillar, and a third insulating layer. The stacked body has conductive layers and insulating layers alternately stacked in a first direction. The pillar extends in the first direction in the stacked body. The third insulating layer has a first portion extending in the first direction between the conductive layer and the second insulating layer. The third insulating layer includes a first layer and a second layer between the first layer and one of the conductive layers. A carbon concentration of the second layer is higher than a carbon concentration of the first layer.

### CROSS-REFERENCE TO RELATED APPLICATIONS

This application is based upon and claims the benefit of priority from Japanese Patent Application No. 2025-039686, filed Mar. 12, 2025, the entire contents of which are incorporated herein by reference.

### FIELD

Embodiments described herein relate generally to a semiconductor storage device and a manufacturing method thereof.

### BACKGROUND

For a three-dimensional nonvolatile memory having a plurality of memory cells stacked on a semiconductor substrate, reliability of data retention characteristics and/or the like is desirable.

### BRIEF DESCRIPTION OF THE DRAWINGS

FIG. 1 is a diagram schematically showing a planar pattern of a basic configuration of a semiconductor storage device according to a first embodiment;

FIG. 2 is a cross-sectional diagram showing a cross section taken along the A-A line in FIG. 1;

FIG. 3 is a cross-sectional diagram schematically showing a detailed configuration of a pillar structure, a segment structure, and the like of the semiconductor storage device according to the first embodiment;

FIG. 4 is a cross-sectional diagram schematically showing a detailed configuration of the pillar structure, the segment structure, and the like of the semiconductor storage device according to the first embodiment;

FIG. 5 is a cross-sectional diagram showing an example of a configuration of the semiconductor storage device according to the first embodiment;

FIG. 6 is a cross-sectional diagram showing an example of a configuration of the semiconductor storage device according to the first embodiment;

FIG. 7A is a cross-sectional diagram showing an example of a manufacturing method of the semiconductor storage device according to the first embodiment;

FIG. 7B is a cross-sectional diagram, subsequent to FIG. 7A, showing an example of the manufacturing method of the semiconductor storage device;

FIG. 7C is a cross-sectional diagram, subsequent to FIG. 7B, showing an example of the manufacturing method of the semiconductor storage device;

FIG. 8A is a cross-sectional diagram showing an example of the manufacturing method of the semiconductor storage device according to the first embodiment;

FIG. 8B is a cross-sectional diagram, subsequent to FIG. 8A, showing an example of the manufacturing method of the semiconductor storage device;

FIG. 8C is a cross-sectional diagram, subsequent to FIG. 8B, showing an example of the manufacturing method of the semiconductor storage device;

FIG. 8D is a cross-sectional diagram, subsequent to FIG. 8C, showing an example of the manufacturing method of the semiconductor storage device;

FIG. 9 is a cross-sectional diagram showing an example of a configuration of a semiconductor storage device according to a comparative example;

FIG. 10 is a graph showing an example of distributions of carbon concentrations according to the first embodiment and the comparative example;

FIG. 11 is a cross-sectional diagram showing an example of a configuration of a semiconductor storage device according to a second embodiment;

FIG. 12 is a cross-sectional diagram showing an example of a manufacturing method of the semiconductor storage device according to the second embodiment; and

FIG. 13 is a cross-sectional diagram showing an example of a configuration of a semiconductor storage device according to a third embodiment.

### DETAILED DESCRIPTION

There are provided a semiconductor storage device capable of securing higher reliability, and a manufacturing method thereof.

In general, according to an embodiment, a semiconductor storage device includes: a stacked body; a semiconductor layer; a first insulating layer; a charge storage layer; a second insulating layer; and a third insulating layer. The stacked body has a plurality of conductive layers and a plurality of insulating layers alternately stacked in a first direction. The semiconductor layer extends in the first direction in the stacked body. The first insulating layer extends in the first direction between the stacked body and the semiconductor layer. The charge storage layer extends in the first direction between the stacked body and the first insulating layer. The second insulating layer extends in the first direction between the stacked body and the charge storage layer. The third insulating layer has a first portion and a second portion, the first portion extends in the first direction between one of the plurality of conductive layers and the second insulating layer, and the second portion extends in a second direction intersecting the first direction between the one of the conductive layers and each of adjacent two of the plurality of insulating layers and connects to the first portion. The third insulating layer includes a first layer and a second layer between the first layer and the one of the conductive layers at each of the first and second portions. A carbon concentration of the second layer is higher than a carbon concentration of the first layer.

Hereafter, embodiments according to the present invention will be described with reference to the drawings. The presented embodiments do not limit the scope of the present invention. The drawings are schematic or conceptual, and proportions of portions and the like are not necessarily the same as real ones. In the specification and the drawings, the similar elements to those described regarding the drawings that are previously presented are given the same signs, and detailed description of those is properly omitted.

### First Embodiment

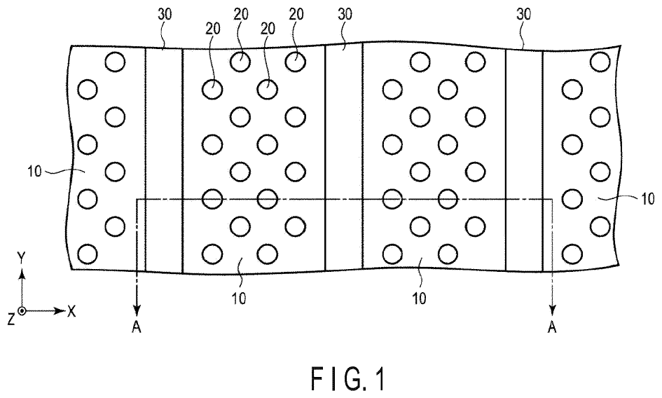

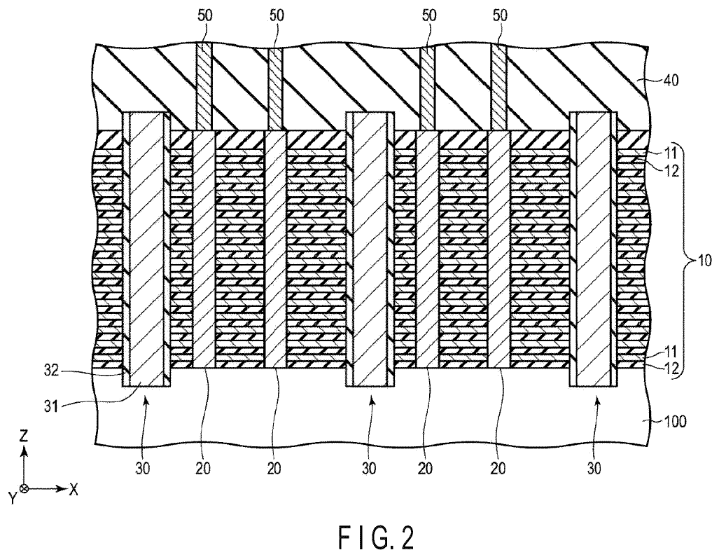

FIG. 1 is a diagram schematically showing a planar pattern of a basic configuration of a semiconductor storage device (NAND nonvolatile semiconductor storage device) according to a first embodiment. FIG. 2 is a cross-sectional diagram showing a cross section taken along the A-A line in FIG. 1. Notably, an X-direction, a Y-direction, and a Z-direction shown in the drawings are directions intersecting one another. Specifically, the X-direction, the Y-direction, and the Z-direction are directions perpendicular to one another.

As shown in FIG. 1 and FIG. 2, the semiconductor storage device according to the first embodiment includes a stacked body 10, a plurality of pillar structures 20, a plurality of segment structures 30, an interlayer insulating layer 40, and a plurality of contacts 50.

The stacked body 10 is provided on a semiconductor substrate 100, and has a structure in which a plurality of conductive layers 11 and a plurality of insulating layers 12 are alternately stacked in the Z-direction. Namely, the plurality of conductive layers 11 are stacked to be spaced from one another in the Z-direction, and the plurality of conductive layers 11 are electrically insulated by the plurality of insulating layers 12.

The conductive layers 11 are formed of molybdenum (Mo). The insulating layers 12 are formed of an insulating material such as silicon oxide. Both the conductive layers 11 and the insulating layers 12 are provided to be parallel to the XY-plane perpendicular to the Z-direction. The conductive layers 11 function as electrode layers. Specifically, each conductive layer 11 functions as a word line or a select gate line.

Each of the pillar structures 20 extends in the stacked body 10 in the Z-direction and includes a semiconductor layer extending in the Z-direction and a charge storage layer enclosing a lateral surface of the semiconductor layer, and a lower end of the semiconductor layer is connected to a common source region. Herein, a well region of the semiconductor substrate 100 may function as the common source region, or source lines as the common source region may be formed on the substrate via various elements, lines, and the like constituting a peripheral circuit.

The pillar structure 20 is enclosed by the plurality of conductive layers 11 and the plurality of insulating layers 12. The pillar structure 20 and the plurality of conductive layers 11 enclosing the pillar structure 20 form a NAND string including a plurality of memory cells connected in series and a plurality of select transistors provided on both sides of the plurality of memory cells connected in series.

Specifically, the conductive layers 11 enclosing the pillar structure 20 function as gate electrodes, and the memory cells and the select transistors are constituted by portions, of the conductive layer 11, that function as the gate electrodes and portions, of the pillar structure 20, that are enclosed by the conductive layers 11. Namely, the memory cells are formed of the conductive layers 11 that function as word lines and portions, of pillar structure 20, that are enclosed by the conductive layer 11 functioning as the word lines. Moreover, the select transistors are formed of the conductive layers 11 that function as select gate lines and portions, of pillar structure 20, that are enclosed by the conductive layers 11 functioning as the select gate lines.

Each of the segment structures 30 extends in the stacked body 10 in the Y-direction and the Z-direction. The stacked body 10 is divided into a plurality of portions in the X-direction by the plurality of segment structures 30, and the pillar structures 20 are segmented into a plurality of groups in the X-direction. The segment structures 30 are arranged at substantially equal intervals in the X-direction, and a column number of pillar structures 20 that are arranged between adjacent segment structures 30 is constant. Each of regions divided by the segment structures 30 forms, for example, one block as an erasing unit of data.

The segment structures 30 are formed by filling slits used for replacing processing mentioned later with a predetermined material, and each of them includes a conductive portion 31 formed of a conductive material, and an insulating portion 32 formed of an insulating material. For example, the conductive portion 31 has a lower end connected to the common source region of the semiconductor substrate 100, and functions as a source contact. Notably, the segment structures 30 may be formed by filling the slits after the replacing processing only with an insulating material without the conductive material functioning as source contacts being formed therein.

A structure including the stacked body 10, the pillar structures 20, and the segment structures 30 is covered by the interlayer insulating layer 40. Moreover, the plurality of contacts 50 penetrate the interlayer insulating layer 40, and the plurality of contacts 50 have lower ends connected to the semiconductor layers of the plurality of pillar structures 20, and upper ends connected to bit lines, for example, via vias.

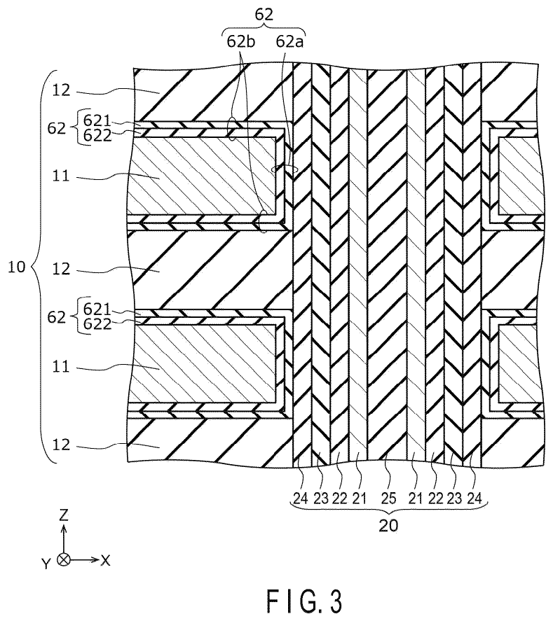

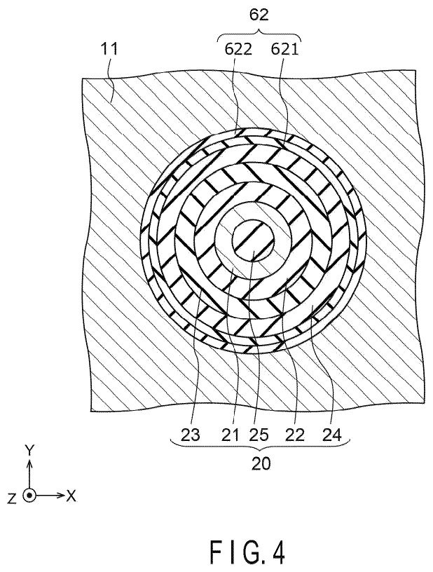

FIG. 3 and FIG. 4 are cross-sectional diagrams schematically showing a detailed configuration of the pillar structure 20 and the like. FIG. 3 is a cross-sectional diagram showing a cross section in a direction parallel to the Z-direction, and FIG. 4 is a cross-sectional diagram showing a cross section in a direction perpendicular to the Z-direction.

Each of the pillar structures 20 includes a semiconductor layer 21, a tunnel insulating layer 22, a charge storage layer 23, a block insulating layer 24, and a core insulating layer 25. Each of the semiconductor layer 21, the tunnel insulating layer 22, the charge storage layer 23, and the block insulating layer 24 has a cylindrical shape, and the core insulating layer 25 has a columnar shape. More specifically, the semiconductor layer 21 encloses a lateral surface of the core insulating layer 25, the tunnel insulating layer 22 encloses a lateral surface of the semiconductor layer 21, the charge storage layer 23 encloses a lateral surface of the tunnel insulating layer 22, and the block insulating layer 24 encloses a lateral surface of the charge storage layer 23. For example, the semiconductor layer 21 is formed of silicon, the tunnel insulating layer 22 is formed of silicon oxide, the charge storage layer 23 is formed of silicon nitride, the block insulating layer 24 is formed of silicon oxide, and the core insulating layer 25 is formed of silicon oxide.

On an outer side of the pillar structure 20, block insulating layers 62 are provided. Specifically, each of the block insulating layers 62 includes a first portion 62a provided between the pillar structure 20 and the conductive layer 11, and second portions 62b provided between the conductive layer 11 and the insulating layers 12. The second portions 62b are connected to the first portion 62a.

For example, the block insulating layers 62 include a compound of aluminum (Al) and oxygen (O) (aluminum oxide, Al₂O₃).

Each of the block insulating layer 62 has two or more layers. More in detail, the block insulating layer 62 has two or more block insulating layers different in characteristics in a film thickness direction of the block insulating layer 62. As described later, a carbon concentration in a layer of the block insulating layer 62 on the conductive layer 11 side is higher than a carbon concentration in another layer of the block insulating layer 62.

In the example shown in FIG. 3, each of the block insulating layers 62 has a first layer 621 and a second layer 622. The first layers 621 and the second layers 622 are provided along the upper and lower surfaces of the insulating layers 12 and along the lateral surface of the block insulating layer 24.

Each of the first layers 621 is a layer on the side of the pillar structure 20 and the insulating layers 12. For example, the first layer 621 includes a compound of aluminum (Al) and oxygen (O) (aluminum oxide, Al₂O₃).

Each of the second layers 622 is a layer on the conductive layer 11 side. Namely, the second layer 622 is provided closer to the conductive layer 11 than the first layer 621. For example, the second layer 622 includes a compound of aluminum (Al) and oxygen (O) (aluminum oxide, Al₂O₃).

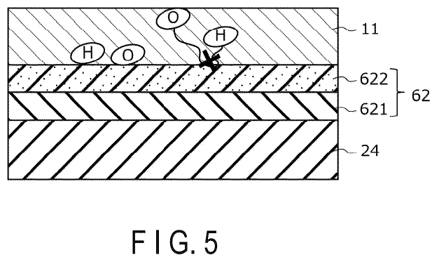

FIG. 5 is a cross-sectional diagram showing an example of a configuration of the semiconductor storage device according to the first embodiment. FIG. 5 illustrates also an expanded cross-sectional view having a region between the block insulating layer 24 and the conductive layer 11 expanded. FIG. 5 also shows diffusion of oxygen (oxygen radical) and hydrogen (hydrogen radical). Notably, the first layer 621 and the second layer 622 are also provided on the insulating layer 12.

A carbon concentration in the second layer 622 is higher than a carbon concentration in the first layer 621. The carbon concentration in the first layer 621 is less than 1×10²⁰ atoms/cm³, for example. The carbon concentration in the second layer 622 is not less than 1×10²⁰ atoms/cm³, for example.

Carbon (C) traps oxygen and hydrogen. Accordingly, the second layer 622 including carbon restrains diffusion of oxygen (O) and hydrogen (H) diffusing from the conductive layer 11 to the pillar structure 20 (block insulating layer 24). For example, the oxygen is originated from MoO₂Cl₂ included in a film deposition gas (raw material gas) in forming the conductive layer 11. For example, the hydrogen is originated from hydrogen (H₂) as a reducing gas.

By restraining the diffusion of oxygen and hydrogen, a trap level can be restrained from being generated in the block insulating layer 24, and thus, causing deterioration in data retention characteristics, as described later. As a result, characteristics or reliability of the semiconductor storage device can be restrained from deteriorating.

Moreover, the layer including carbon (second layer 622) is preferably on a side close to the conductive layer 11. This is because, even when oxygen and hydrogen diffuse beyond the second layer 622 caused by some influence, a distance of moving of those to the block insulating layer 24 can be elongated.

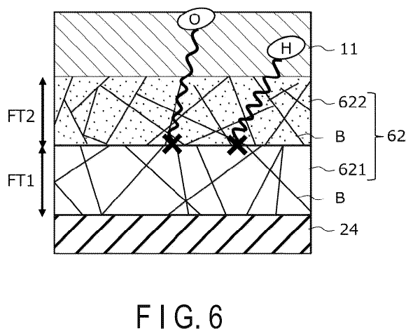

FIG. 6 is a cross-sectional diagram showing an example of a configuration of the semiconductor storage device according to the first embodiment. FIG. 6 shows grain boundaries B in the first layer 621 and the second layer 622.

The first layer 621 and the second layer 622 are crystallized films including crystal grains. The first layer 621 and the second layer 622 have grain boundaries B. The crystal grains of the first layer 621 and the second layer 622 are parted at the boundary surface between the first layer 621 and the second layer 622 in contact with each other. Namely, the crystal grains of the first layer 621 and the second layer 622 are parted in the film thickness direction. Accordingly, paths for the diffusion can be made complex. Moreover, the boundary surface itself also traps diffusing oxygen and hydrogen. Thereby, oxygen and hydrogen diffusing along grain boundaries B in the second layer 622 can be trapped at the boundary surface between the first layer 621 and the second layer 622. Thereby, diffusion of oxygen and hydrogen diffusing from the conductive layer 11 to the block insulating layer 24 can be restrained.

A film thickness FT1 of the first layer 621 is not less than 1 nm, for example. A film thickness FT2 of the second layer 622 is less than 1 nm, for example.

Next, a forming method of the stacked body 10 including the first layers 621 and the second layers 622 is described.

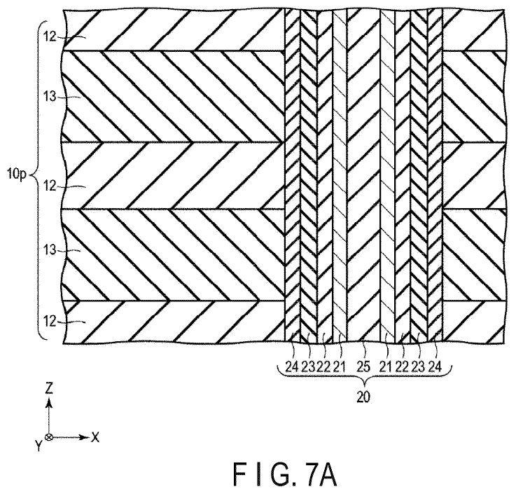

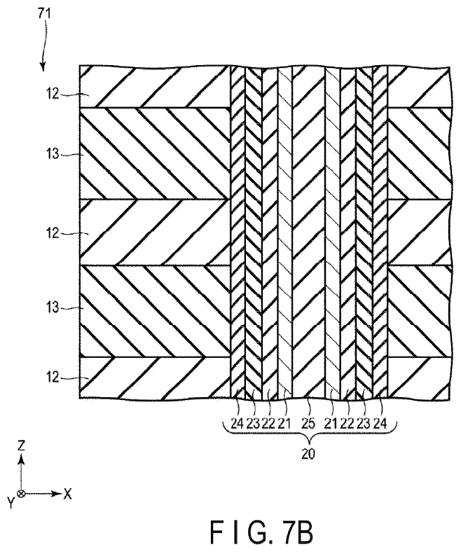

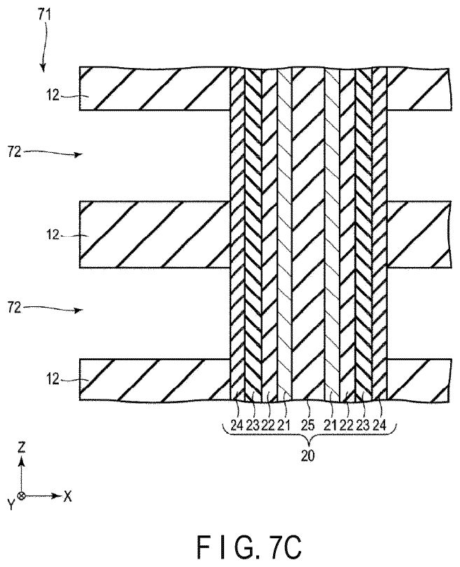

FIG. 7A to FIG. 7C are cross-sectional diagrams showing an example of a manufacturing method of the semiconductor storage device according to the first embodiment.

First, as shown in FIG. 7A, a preliminary stacked body 10p having sacrificial layers 13 and the insulating layers 12 alternately stacked in the Z-direction is formed. Next, the pillar structure 20 extending in the Z-direction across the preliminary stacked body 10p is formed.

Next, as shown in FIG. 7B, patterning on the preliminary stacked body 10p is performed thereby to form a slit 71 that penetrates the preliminary stacked body 10p and extends in the Y-direction and the Z-direction.

Next, as shown in FIG. 7C, the sacrificial layers 13 are removed such that the block insulating layer 24 is exposed. Namely, the sacrificial layers 13 are etched via the slit 71, and the sacrificial layers 13 are removed. Thereby, a plurality of vacant places 72 each provided between adjacent insulating layers 12 are formed.

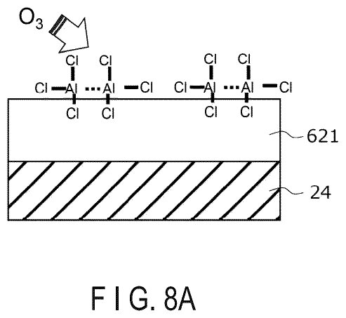

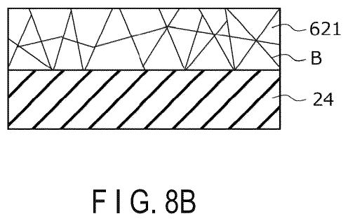

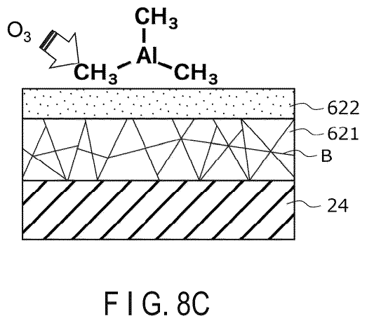

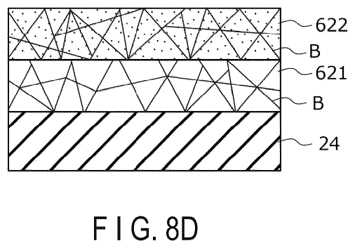

FIG. 8A to FIG. 8D are cross-sectional diagrams showing an example of the manufacturing method of the semiconductor storage device according to the first embodiment. The steps shown in FIG. 8A to FIG. 8D are performed subsequently to the steps shown in FIG. 7A to FIG. 7C. FIG. 8A to FIG. 8D illustrate also expanded cross-sectional views having the block insulating layer 24, the first layer 621, and the second layer 622 expanded.

First, as shown in FIG. 8A, the first layer 621 is formed on the block insulating layer 24. More in detail, the first layer 621 of insulator is formed on the block insulating layer 24 and the insulating layers 12 in each of the spaces obtained by removing the sacrificial layers 13 (the plurality of vacant places 72 shown in FIG. 7C). The formed first layer 621 is an amorphous film. The first layer 621 is formed, for example, through film deposition of Al₂O₃ with AlCl₃ being as a raw material. The raw material of the first layer 621 does not include carbon, for example.

Next, as shown in FIG. 8B, the first layer 621 is crystallized by performing annealing processing. Namely, the first layer 621 as the amorphous film becomes a crystallized film. For example, the annealing processing is PDA (Post Deposition Annealing).

Next, as shown in FIG. 8C, the second layer 622 is formed on the first layer 621. More in detail, the second layer 622 of insulator including carbon (C) is formed on the first layer 621. The formed second layer 622 is an amorphous film. The second layer 622 is formed, for example, through film deposition of Al₂O₃ with TMA (Trimethylaluminum) being as a raw material. The raw material of the second layer 622 is a raw material including carbon, not being limited to TMA.

Next, as shown in FIG. 8D, the second layer 622 is crystallized by performing annealing processing. Namely, the second layer 622 as the amorphous film becomes a crystallized film. For example, the annealing processing is PDA.

After that, by filling the spaces obtained by removing the sacrificial layers 13 with the conductive layers 11, the stacked body 10 shown in FIG. 3 is formed. Moreover, by forming the insulating portion 32 and the conductive portion 31 in the slit 71, the segment structure 30 shown in FIG. 2 is formed.

As above, according to the first embodiment, the block insulating layer 62 has two or more layers. The carbon concentration in the layer of the block insulating layer 62 on the conductive layer 11 side is higher than the carbon concentration in another layer of the block insulating layer 62. Carbon traps oxygen and hydrogen. By providing the layer (second layer 622) having a relatively high carbon concentration, diffusion of oxygen and hydrogen diffusing from the conductive layer 11 to the block insulating layer 24 can be restrained. Accordingly, a trap level can be restrained from being generated in the block insulating layer 24, and thus, causing deterioration in data retention characteristics. As a result, characteristics or reliability of the semiconductor storage device can be restrained from deteriorating.

Notably, the second layer 622 may have a carbon concentration that is gradually decreasing from the conductive layer 11 side toward the insulating layers 12 and the pillar structure 20. For example, by feeding gas including carbon, such as acetylene (C₂H₂) gas, during film deposition of the second layer 622, the carbon concentration of the second layer 622 can be changed in accordance with the thickness direction.

Moreover, while there has been described the case where the block insulating layer 62 has two layers, the block insulating layer 62 may have three or more layers. Moreover, by changing types of the raw material gas including carbon, layers different in carbon concentration may be formed. For example, by forming a plurality of layers by changing the types of the raw material gas including carbon, the block insulating layer 62 having three or more layers different in carbon concentration can be formed.

Moreover, the raw material gas of the conductive layers 11 is not limited to MoO₂Cl₂ and, for example, may include a metal chloride such as MoCl₅. Notably, even when oxygen is not included in the raw material, oxygen possibly diffuses from an oxidized portion, for example, with a wafer surface oxidized during manufacturing steps.

Moreover, the conductive layers 11 may include cobalt (Co), nickel (Ni), or the like, not being limited to Mo. For example, the raw material gas of the conductive layers 11 includes a metal chloride such as CoCl₅.

### Comparative Example

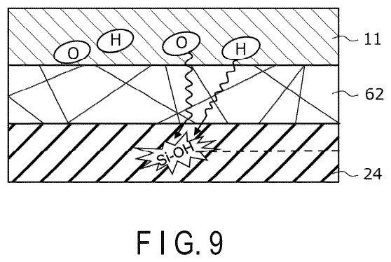

FIG. 9 is a cross-sectional diagram showing an example of a configuration of a semiconductor storage device according to a comparative example. The comparative example is different from the first embodiment in that the second layers 622 are not provided.

A film material of the block insulating layer 62 in the comparative example is the same as a film material of the first layer 621 of the first embodiment. The block insulating layer 62 is formed, for example, through film deposition of Al₂O₃ with AlCl₃ being as a raw material.

For example, the conductive layer 11 including Mo is deposited using MoO₂Cl₂ as a Mo raw material and hydrogen (H₂) as a reducing gas. Oxygen and hydrogen originated from the Mo raw material and the reducing gas in the film deposition process of the conductive layer 11 pass through the block insulating layer 62 to diffuse. When the oxygen and the hydrogen reach the block insulating layer 24, an Si—OH bond is formed. As a result, a new level is formed, which causes data retention characteristics to deteriorate.

To the contrary, in the first embodiment, by providing the second layer 622 including carbon which traps oxygen and hydrogen, oxygen and hydrogen can be restrained from diffusing into the block insulating layer 24. Thereby, an OH concentration in the block insulating layer 24 is reduced, and electrons can be restrained from passing through via OH. This can restrain deterioration in data retention characteristics.

Moreover, in the first embodiment, the block insulating layer 62 has a layered structure of two or more layers. Thereby, diffusion of oxygen and hydrogen can be restrained at the boundary surface between the first layer 621 and the second layer 622. This can more restrain oxygen and hydrogen from diffusing into the block insulating layer 24.

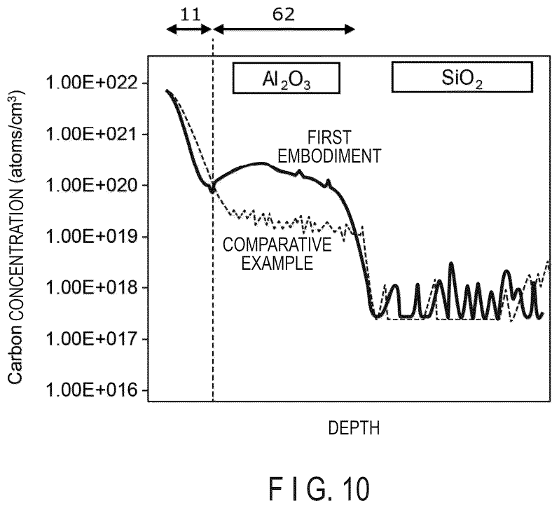

FIG. 10 is a graph showing an example of distributions of the carbon concentrations according to the first embodiment and the comparative example. FIG. 10 shows results of SIMS (Secondary Ion Mass Spectrometry). The axis of abscissas denotes a depth in the Z-direction. The axis of ordinates denotes the carbon concentrations (atoms/cm³).

As shown in FIG. 10, the carbon concentration in the block insulating layer 62 (Al₂O₃) according to the first embodiment is roughly ten times higher than the carbon concentration in the block insulating layer 62 (Al₂O₃) according to the comparative example. Moreover, the carbon concentration in the layer (second layer 622) of the block insulating layer 62 according to the first embodiment on the conductive layer 11 side is not less than 1×10²⁰ atoms/cm³.

Notably, for detection of the carbon concentration, another detection technique may be used, not being limited to SIMS.

### Second Embodiment

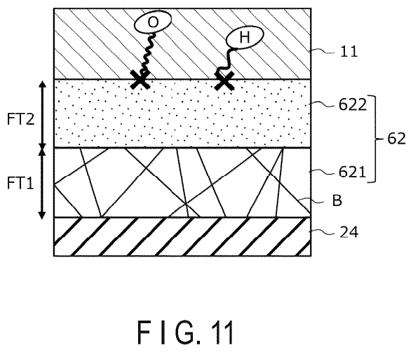

FIG. 11 is a cross-sectional diagram showing an example of a configuration of a semiconductor storage device according to a second embodiment. The second embodiment is different from the first embodiment in that the second layers 622 are amorphous films.

A layer of the block insulating layer 62 on the conductive layer 11 side is an amorphous film. Namely, the second layer 622 is an amorphous film.

The second layer 622 as the amorphous film includes a large amount of impurity. The impurity traps diffusing oxygen and hydrogen. Accordingly, with the second layer 622 as the amorphous film, diffusion of oxygen and hydrogen diffusing from the conductive layer 11 to block insulating layer 24 can be restrained.

Moreover, as described for the first embodiment, the second layer 622 including carbon restrains the diffusion of oxygen (O) and hydrogen (H) diffusing from the conductive layer 11 to the block insulating layer 24.

A carbon concentration in the second layer 622 according to the second embodiment may be higher than the carbon concentration in the second layer 622 according to the first embodiment and, for example, may be not less than 1×10²¹ atoms/cm³. Decrease of carbon through crystallization can be restrained, and hence, the carbon concentration can be made higher. Thereby, diffusion of oxygen and hydrogen diffusing from the conductive layer 11 to the block insulating layer 24 can be more restrained.

Moreover, as described for the first embodiment, the boundary surface between the first layer 621 and the second layer 622 also traps diffusing oxygen and hydrogen. Namely, a boundary surface between the amorphous film and the crystallized film also traps the diffusing oxygen and hydrogen.

Moreover, the film thickness FT2 of the second layer 622 is smaller than the film thickness FT1 of the first layer 621. The film thickness FT1 of the first layer 621 is not less than 1 nm, for example. The film thickness FT2 of the second layer 622 is less than 1 nm, for example. There can be a case where an amorphous film has lower characteristics as an insulating layer than a crystallized film. Accordingly, in view of a withstand voltage and the like, the film thickness of the amorphous film is preferably smaller than the film thickness of the crystallized film.

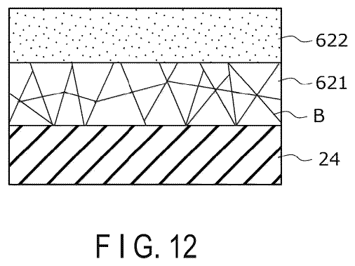

FIG. 12 is a cross-sectional diagram showing an example of a manufacturing method of the semiconductor storage device according to the second embodiment. The step shown in FIG. 12 is performed after the step shown in FIG. 8C.

As shown in FIG. 12, the amorphous state of the second layer 622 is kept. Namely, the annealing processing shown in FIG. 8D is not performed.

As in the second embodiment, the second layers 622 may be amorphous films. The semiconductor storage device according to the second embodiment can obtain the similar effect(s) as with the first embodiment.

### Third Embodiment

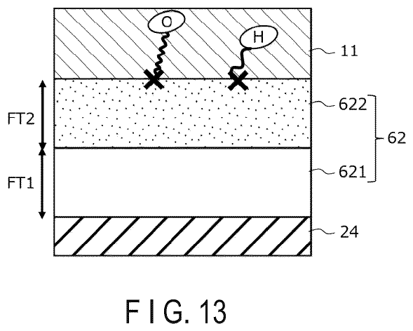

FIG. 13 is a cross-sectional diagram showing an example of a configuration of a semiconductor storage device according to a third embodiment. The third embodiment is different from the second embodiment in that not only the second layers 622 but also the first layers 621 are amorphous films.

A layer of the block insulating layer 62 on the side of the pillar structure 20 and the insulating layers 12 is an amorphous film. Namely, the first layer 621 is an amorphous film.

The first layer 621 as the amorphous film includes a large amount of impurity. The impurity traps diffusing oxygen and hydrogen. Accordingly, with the first layer 621 as the amorphous film, diffusion of oxygen and hydrogen diffusing from the conductive layer 11 to the block insulating layer 24 can be restrained.

Moreover, as described for the first embodiment, the boundary surface between the first layer 621 and the second layer 622 also traps diffusing oxygen and hydrogen. Namely, a boundary surface between the amorphous film and the amorphous film also traps the diffusing oxygen and hydrogen.

A forming method of the first layer 621 and the second layer 622 according to the third embodiment is different from that of the second embodiment in that the crystallization step shown in FIG. 8B is omitted. Namely, the second layer 622 is formed on the first layer 621 with the amorphous state of the first layer 621 being kept.

As in the third embodiment, the first layers 621 may also be amorphous films. The semiconductor storage device according to the third embodiment can obtain the similar effect(s) as with the second embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions, and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device comprising:
a stacked body having a plurality of conductive layers and a plurality of insulating layers alternately stacked in a first direction;
a semiconductor layer extending in the first direction in the stacked body;
a first insulating layer extending in the first direction between the stacked body and the semiconductor layer;
a charge storage layer extending in the first direction between the stacked body and the first insulating layer;
a second insulating layer extending in the first direction between the stacked body and the charge storage layer; and
a third insulating layer having a first portion and a second portion, the first portion extending in the first direction between one of the plurality of conductive layers and the second insulating layer, the second portion extending in a second direction intersecting the first direction between the one of the conductive layers and each of adjacent two of the plurality of insulating layers and connecting to the first portion, wherein
the third insulating layer includes a first layer and a second layer between the first layer and the one of the conductive layers at each of the first and second portions, and
a carbon concentration of the second layer is higher than a carbon concentration of the first layer.

2. The semiconductor storage device according to claim 1, wherein
the carbon concentration of the first layer is less than 1×10²⁰/cm³, and
the carbon concentration of the second layer is equal to or greater than 1×10²⁰/cm³.

3. The semiconductor storage device according to claim 2, wherein
the first layer and the second layer are in contact with each other,
each of the first layer and the second layer is a crystallized film including crystal grains, and
the crystal grains of the first layer and the second layer form a boundary between the first layer and the second layer.

4. The semiconductor storage device according to claim 3, wherein a film thickness of the first layer is equal to or greater than 1 nm.

5. The semiconductor storage device according to claim 2, wherein
the first layer is a crystallized film including crystal grains, and
the second layer is an amorphous film.

6. The semiconductor storage device according to claim 5, wherein a film thickness of the second layer is smaller than a film thickness of the first layer.

7. The semiconductor storage device according to claim 5, wherein
a film thickness of the first layer is equal to or greater than 1 nm, and
a film thickness of the second layer is less than 1 nm.

8. The semiconductor storage device according to claim 2, wherein each of the first layer and the second layer is an amorphous film.

9. The semiconductor storage device according to claim 1, wherein the plurality of conductive layers includes molybdenum (Mo) or cobalt (Co).

10. The semiconductor storage device according to claim 1, wherein the third insulating layer includes a compound of aluminum (Al) and oxygen (O).

11. The semiconductor storage device according to claim 10, wherein each of the first layer and the second layer includes a compound of aluminum (Al) and oxygen (O).

12. The semiconductor storage device according to claim 11, wherein a film thickness of the second layer is smaller than a film thickness of the first layer.

13. The semiconductor storage device according to claim 12, wherein
a film thickness of the first layer is equal to or greater than 1 nm, and
a film thickness of the second layer is less than 1 nm.

14. The semiconductor storage device according to claim 15, wherein the second layer is in contact with the one of the conductive layer at each of the first and second portions.

15. The semiconductor storage device according to claim 14, wherein the first layer is in contact with the second layer at each of the first and second portions.

16. The semiconductor storage device according to claim 1, wherein the second layer is in contact with the one of the conductive layer at each of the first and second portions.

17. The semiconductor storage device according to claim 16, wherein the first layer is in contact with the second layer at each of the first and second portions.

18. A method for manufacturing a semiconductor storage device, the method comprising:
forming a stacked body including a plurality of sacrificial layers and a plurality of insulating layers alternately stacked in a first direction;
forming a pillar structure that extends in the stacked body in the first direction and includes a semiconductor layer, a first insulating layer, a charge storage layer, and a second insulating layer;
removing the plurality of sacrificial layers such that the second insulating layer is exposed;
forming a first layer of insulator on the second insulating layer and adjacent two of the plurality of insulating layers in a space obtained by removing one of the plurality of sacrificial layers; and
forming, on the first layer, a second layer of insulator including carbon (C).

19. The method according to claim 18, wherein a carbon concentration of the second layer is higher than a carbon concentration of the first layer.

20. The method according to claim 18, wherein
said forming the first layer comprises annealing the first layer to crystalize the first layer, and
said forming the second layer comprises annealing the second layer to crystalize the second layer.
